(19) United States
(12) Patent Application Publication
(10) Pub. No.: US 2007/0240826 A1
(43) Pub. Date: Oct. 18, 2007

(54) Gas supply device and apparatus for gas etching or cleaning substrates

(75) Inventors: Liang-Gi Yao, Hsinchu (TW); Chia-Lin Chen, Hsinchu (TW); Ming-Feng Wang, Taichung (TW); Ming-Feng Yoo, Hsinchu (TW); Kuen-Chyr Lee, Tainan (TW); Shih-Chang Chen, Hsinchu (TW)

Correspondence Address: BIRCH STEWART KOLASCH & BIRCH, PO BOX 747, FALLS CHURCH, VA, 22040-0747, US

(73) Assignee: TAIWAN SEMICONDUCTOR MANUFACTURING CO., LTD., Hsin-Chu (TW)

(21) Appl. No.: 11/405,618

(22) Filed: Apr. 18, 2006

(51) Int. Cl. H01L 21/306; C23F 1/00

(52) U.S. Cl. 156/345.29; 156/345.27

(57) ABSTRACT

A gas supply device, including: a first source of an inert carrier gas, communicated with a first pipeline; a second source of anhydrous reactive gas, communicated with a second pipeline; a third source of enabling chemical gas of an enabling chemical compound, communicated with a third pipeline; a main pipeline, communicated with the first, second, and third pipelines; and a temperature controller, located on the second pipeline.

### BACKGROUND

The present invention relates to a gas supply device, and in particular to an etching or cleaning gas supply device.

The effectiveness of cleaning processes for removing contamination from silicon wafers employed for microfabrication is growing ever more important as the critical size of micro fabricated electronic devices shrink. Wafer contamination is generally introduced from wafer production and packaging, from exposure to the ambient, and from human exposure during processing, and can consist of particles, organic residue, adsorbed metal ions, and other contaminants. The vital role of wafer cleaning in microfabrication processing is evidenced by the fact that about one-third of the total number of steps in a given microfabrication process are cleaning steps.

To maximize microfabrication production yield, cleaning processes are relied on to remove wafer contamination without damaging or consuming the wafer and without introducing further contamination to the wafer. For silicon wafers, such cleaning typically includes removal of the native oxide layer that is generally present on the wafer. Metal and other contamination can be trapped in this native oxide layer and can critically contaminate high-temperature processing equipment. Removal of the native oxide layer is therefore generally always carried out as an integral wafer cleaning process before any high-temperature wafer processing.

Traditionally, silicon wafers are cleaned by way of aqueous phase cleaning processes that typically employ acids, bases, and mixtures of various chemicals. Historically, aqueous phase processes have been effective at removing contaminants and the native oxide layer. Now, however, as microelectronic features shrink to the sub-micron regime, the aspect ratio of wafer topology greatly increases, and the microelectronic metal interconnect layers are increased, traditional aqueous cleaning processes are less effective or completely ineffective. Thorough drying of rinse solutions from around and in small or high aspect ratio features can be difficult and can result in trapping of contamination at those features. Furthermore, new combinations of microelectronic materials and new exotic microelectronic materials can be adversely affected by aqueous cleaning chemicals that historically were considered benign to more conventional materials.

Besides, the natural oxide film formed on a silicon substrate is very thin. It follows that it is difficult to control the etching uniformity to etch selectively the natural oxide film alone, leading to the problem that oxide film other than the natural oxide film tends to be etched together with the natural oxide film. Further, the etching rate in a peripheral region is higher than that in a central portion, when it comes to a single wafer. In other words, the conventional dry etching method is not satisfactory in uniformity of etching rate over the entire surface of a single wafer.

Thus, it can be seen that the particular concerns of lack of process uniformity control and unwanted process contamination is generated as described above, moreover, it has historically been considered extremely difficult to guarantee contamination film etch/removal process repeatability or predictability of efficiency of uniformity with respect to starting wafer conditions such as contamination conditions. These various concerns, taken together, are generally considered to outweigh the potential benefits that contamination film etch/removal cleaning and etching might bring to micro-fabrication process efficiency, precision, economics, and environmental regulatory compliance.

In response to many of these issues, the use of an anhydrous reactive gas, such as hydrofluoric acid (HF) vapor, for cleaning silicon wafers, including etching of native oxide, and etching of thicker silicon dioxide layers, has been extensively studied.

### SUMMARY

A gas supply device is provided. An exemplary embodiment of a gas supply device comprises: a first source of an inert carrier gas, communicated with a first pipeline; a second source of anhydrous reactive gas, communicated with a second pipeline; a third source of enabling chemical gas of an enabling chemical compound, communicated with a third pipeline; a main pipeline, communicated with the first, second, and third pipelines; and a temperature controller, located on the second pipeline. Since a second source of anhydrous reactive gas communicated with a second pipeline on which a temperature controller is disposed, the second pipeline can be maintained at a predetermined temperature range. Moreover, the anhydrous reactive gas resident in the second pipe can also reach a certain range of temperature.

An embodiment of an apparatus for gas etching or cleaning a substrate comprises a processing chamber for receiving and treating the substrate and a gas supply device for supplying a gas mixture to the processing chamber. The gas supply device further comprises: a first source of an inert carrier gas, communicated with a first pipeline; a second source of anhydrous reactive gas, communicated with a second pipeline; a third source of enabling chemical gas of an enabling chemical compound, communicated with a third pipeline; a main pipeline, communicated with the first, second, and third pipelines; and a temperature controller, located on the second pipeline.

### DESCRIPTION OF THE DRAWINGS

The invention can be more fully understood by reading the subsequent detailed description and examples with references made to the accompanying drawings, wherein:

FIG. 1 is a gas supply device for providing an etching gas mixture of an embodiment of a gas supply device.

FIG. 2 is a block diagram of an embodiment of an apparatus for gas etching or cleaning a substrate.

### DETAILED DESCRIPTION

A gas supply device for providing an etching gas mixture may not always provide adequate etching uniformity, therefore, an apparatus for etching or cleaning a substrate providing adequate etching uniformity is a key benefit of the invention.

An embodiment of the invention provides a gas supply device for providing an etching gas mixture with good etching uniformity, by applying a gas supply device with a temperature controller thereon to remove an oxide film.

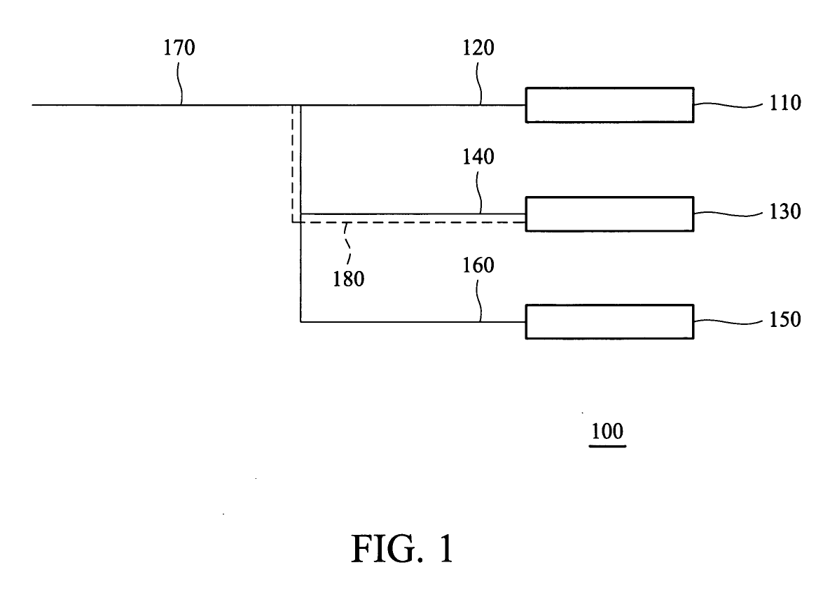

FIG. 1 shows an exemplary device 100 for carrying out the anhydrous reactive gas system of the invention. The gas supply device 100 of the invention is illustrated in block diagram form. The gas supply device 100 for providing an etching gas mixture comprises: a first source of an inert carrier gas 110, communicated with a first pipeline 120; a second source of anhydrous reactive gas 130, communicated with a second pipeline 140; a third source of enabling chemical gas of an enabling chemical compound 150, communicated with a third pipeline 160; a main pipeline 170, communicated with the first, second, and third pipelines; and a temperature controller 180, located on the second pipeline 140.

A source of anhydrous reactive gas 130 can be selected from reactive gas capable of providing a steady flow of anhydrous halogen-containing gas, such as gaseous hydrogen fluoride, and hydrazine, ammonia, carbon dioxide and oxides of nitrogen. The hydrogen fluoride source may be supplied as a liquid in a cylinder, and then evaporated at a temperature sufficient to ensure free flow of the gaseous hydrogen fluoride from the source. In general, the source of hydrogen fluoride is maintained at a suitable temperature ensuring that the hydrogen fluoride is maintained in an anhydrous state. Accordingly, the supply anhydrous hydrogen fluoride is maintained at about 43° C.

The temperature controller 180 attached on the second pipeline 140 may be kept a constant temperature range to prevent condensation of anhydrous reactive gas molecules and stabilize the anhydrous reactive gas system therein, particularly when operated with little or no dilution of the carrier gas. As long as the second pipeline 140 is not heated so high that the vapor pressure is insufficient to drive the anhydrous reactive gas molecules, such heating will allow the device to be constructed. Therefore, it is a significant function that the temperature controller 180 maintains the sufficiently high temperature, preferably from 30° C. to 70° C. Also, when the process is run at ambient temperature (as is typical for the processes of primary commercial interest), such a temperature controller 180 allows the device to be utilized effectively anywhere in the world without concern that variation in ambient temperature might require modification to prevent molecular condensation problems. The temperature controller 180 can be in the form of any formation existing in the gas supply device 100, preferably a heating tape.

Generally, the second source of an anhydrous reactive gas 130 keeps a first temperature for stabilizing molecular structure, and the temperature controller 180, preferably a heating tape attached on the second pipeline 140, keeps a second temperature similar to the first temperature, preferably from 30° C. to 70° C.

The reaction gas may be derived from any source which will provide a steady flow of anhydrous halogen-containing gas and which will remain in an entirely gaseous state throughout the reaction system. Hydrogen fluoride is the preferred halogen-containing gas for use in this process. For instance, pure anhydrous hydrogen fluoride may be used as a source.

An especially preferred source is anhydrous hydrogen fluoride stored as a liquid under its own vapor pressure. It is preferred due to control of reaction rate and uniformity of removal across the wafer surface.

Although, anhydrous hydrogen fluoride is the preferred gas used in the etching process according to this embodiment, other halogen containing gases can potentially be substituted. These may be such gases as anhydrous halogen gases, including chlorine, bromine, fluorine, and iodine, hydrohalogen gases, including hydrogen iodine, hydrogen bromide, and hydrogen chloride.

The inert carrier gas 110 used in the present process may be any gas which is inert to the materials to be treated and which will remain in the gaseous phase under the process conditions present. Suitable gases include the noble gases, such as nitrogen, argon, neon, argon, helium, krypton and xenon. A particularly preferred inert gas according to the invention is nitrogen. Preferably pure nitrogen is used in the present process, such as chromatographic nitrogen.

The inert carrier gas 110 is used both in purging the process chamber and the connected system gas lines before and after the reaction procedure, and in diluting the reactive gas and in preparing the water vapor laden inert gas which is mixed with the reactive gas to form the etchant medium. As described, the inert gas may be the same or different inert gas. Nitrogen is particularly preferable for use as both the dry and the water vapor laden inert gases in the present process.

A source of inner carrier gas 110, such as dry nitrogen, is provided, and it is important that the nitrogen source be of ultra high purity, for example, bottled chromatographic grade dry nitrogen. The source of nitrogen is maintained at room temperature.

A source of enabling chemical gas of an enabling chemical compound 150, such as water vapor generation, is provided. The water source should be of high purity, for example, deionized water.

In addition to enabling chemicals such as water, and alcohols such as methanol, ethanol and isopropanol, other organic liquid HF etch enabling chemicals may be used. For instance ketones, such as acetone and methyl ethyl ketone; aldehydes, such as formaldehyde and acetaldehyde; and carboxylic acids, such as formic acid and acetic acid; can be useful in some circumstances. Isopropanol is preferred.

Typically, the etching gas mixture in the gas supply device 100 is adapted for etching an oxide film thereby keeping etching uniformity below 2%.

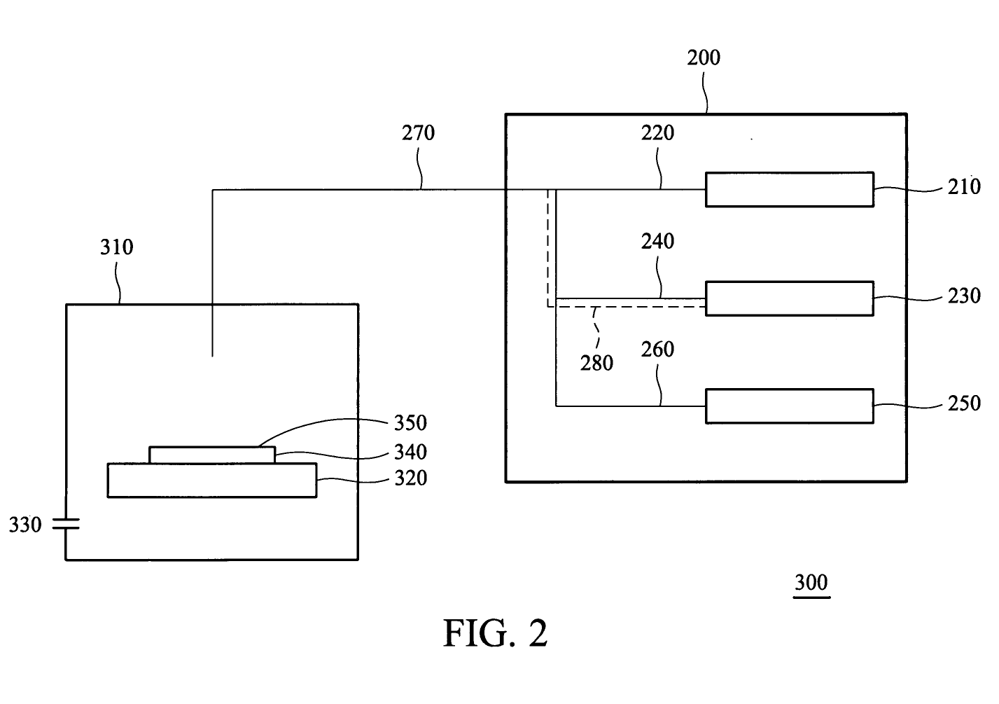

FIG. 2 shows an apparatus for gas etching or cleaning a substrate, which is adapted for combining the gas supply device of the described embodiment. In one example, the manufacturing apparatus 300 is illustrated in block diagram form. As shown in the drawing, a processing chamber 310 is supplied with processing gas via a main pipeline 270. Communicated with the main pipeline 270 are separate lines, first pipeline 220, second pipeline 240, third pipeline 260 leading respectively to sources a first source 210, a second source 230, a third source 250, of, respectively, an inert carrier gas such as nitrogen, anhydrous reactive gas, a gas phase enabling chemical compound. Furthermore, a temperature controller 280 is located on the second pipeline 240.

In FIG. 2, the wafer to be etched is indicated, denoted by 340 and the face of the wafer being subjected to the etching or cleaning reaction is indicated by 350. As has been previously discussed, the films that may be on the face 350 of the wafer 340 that will be removed either completely or selectively may comprise silicon dioxide, polysilicon dioxide, silicon nitride, or others as previously mentioned in such instances. Although described above in connection with a silicon wafer substrate, other substrates may also be employed in the invention. For instance substrates of other semiconductor materials such as SiGe; as well as flat panels; magnetic media and disk drive parts may require an etching operation for which the inventive process and apparatus is particularly suited.

In the drawing there is illustrated a suitable apparatus for carrying out the process wherein the substrate to be etched is a single face 350 of a wafer 340 to be later processed into semiconductor integrated circuit chips. A process chamber 310 can be opened and closed. Exhausts 330 are provided in the process chamber 310 and are normally vented open to the atmosphere to allow for exit of the purging gas and the etching gas during the various phases of the process. The exhausts 330 are sufficiently open as to avoid creating any significant back pressure in the process chamber. The process chamber 310 may be constructed of any material, which will be inert to the etchant gas under the process conditions. Suitable materials include, for example, stainless steel.

The wafer 340 is supported on a turntable horizontal 320, so that its upper face 350, which is being subjected to cleaning or etching is entirely free, clear and unobstructed.

The substrate materials which can be treated by the present process can, generally, be any type of substrate material which will be unaffected by the halogen-containing gaseous etchant medium. When the substrate material is a wafer to be processed in the manufacture of integrated circuit chips, it will typically be composed of such materials as silicon, polysilicon, garnet, binaries such as gallium arsenide and indium phosphide, also ternaries such as CdHgTe, GaAlAs and GalnP, and quaternaries such as GalnAsP. Other substrate materials which may be treated by this etching, cleaning, and/or polishing process include stainless steel, quartz, aluminum, germanium, gallium and selenium.

Such wafer substrates may be etched one at a time, or a plurality may be etched simultaneously. An entire boat or carrier of twenty-five wafers may be simultaneously etched in a larger processing chamber.

These different substrates can have films with varying characteristics. The oxide films on silicon wafers may be thermally grown, by application of oxygen under high temperature conditions; or may be vapor generated with steam and oxygen at elevated temperatures; or the film may result from a chemical vapor deposition process. In addition, the oxide films on the silicon wafers may be doped with such materials as phosphorous, arsenic, or boron. These different films may be etched with this invention. It has been specifically found that films doped with phosphorous will etch with this present invention. Most of the work and etching according to the invention has been done in connection with the oxygen and vapor grown films.

It has been found that the thermally grown films are the most dense and have the slowest etching rate, thus, some adjustment in the concentration of the anhydrous reactive gas in the etching process is required. The vapor generated films grown in vapor and oxygen at elevated temperatures are common films encountered in etching silicon wafers and are considered to be rather typical of the films etched. These vapor generated films are more readily etched at lower concentrations of the reactive gas than are required for etching the thermally grown films. The films produced by chemical vapor deposition are less dense than the usual films encountered and are rapidly etched with low concentrations of the reactive gas.

The doped films are highly etchable with anhydrous reactive gas, such as anhydrous hydrogen fluoride gas and require only diluted concentrations of the reactive gas to accomplish the necessary etching. Such doped films are hygroscopic and may be readily etched without the addition of water vapor mixed with the inert gas.

Silicon substrates may have a layer of polysilicon thereon, and the polysilicon may have an oxide film thereon which may be partially or entirely etched away in the same manner that silicon dioxide is etched.

In general, the etching process is carried out by mixing small quantities of anhydrous reactive gas, preferably an anhydrous hydrogen fluoride gas, with substantial quantities of dry inert gas, preferably nitrogen gas, which acts as a dilutant for the anhydrous reactive gas, and also mixing small quantities of water vapor laden nitrogen. The mixed gases are flowed into the process chamber 310 as to expose the film on the face 350 of the wafer 340 to the diluted reactive gas, and the small quantities of water vapor causes the reaction between the oxide film and the anhydrous reactive gas to be initiated and sustained through duration of the etching process.

As described, the etching process involves a pre-purge, with the dry nitrogen gas, then the actual etching of the film from wafer 340 while the reactive gas is flowed into and through the process chamber 310, and finally a post purge after flow of the reactive gas is terminated.

In the etching process of removing silicon dioxide from the face of a silicon wafer, the resultant products are and remain in vapor form. The actual etching process is very complex, being comprised of several steps. The formal mechanisms of reaction are not clear, but the experiments performed during the development of the process suggest the following explanation. In the course of etching the surface, anhydrous reactive gas vapors, such as hydrogen fluoride vapors, remove silicon dioxide by a chemical reaction that converts the solid SiO₂ to a gaseous form, probably SiF4.

If the apparatus is desired to be operated exclusively without carrier gas, those skilled in the art will recognize that the source of carrier gas can be eliminated from the apparatus without departing from the scope and spirit of the invention.

While this invention may be embodied in many different forms, there are shown in the drawings and described in detail herein specific preferred embodiments of the invention. The present disclosure is an exemplification of the principles of the invention and is not intended to limit the invention to the particular embodiments illustrated. Those skilled in the art may recognize other equivalents to the specific embodiment described herein which equivalents are intended to be encompassed by the claims attached hereto.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A gas supply device, comprising:
a first source of an inert carrier gas, communicated with a first pipeline;
a second source of anhydrous reactive gas, communicated with a second pipeline;
a third source of enabling chemical gas of an enabling chemical compound, communicated with a third pipeline;
a main pipeline, communicated with the first, second, and third pipelines for supplying a gas mixture of the inert carrier gas, the anhydrous reactive gas, the enabling chemical gas of the enabling chemical compound; and
a temperature controller, located on the second pipeline.

2. The device as claimed in claim 1, wherein the temperature controller comprises a heating tape attached to the second pipeline.

3. The device as claimed in claim 1, wherein the second source of an anhydrous reactive gas keeps a first temperature for stabilizing the molecular structure.

4. The device as claimed in claim 3, wherein the temperature controller keeps a second temperature similar to the first temperature.

5. The device as claimed in claim 4, wherein the temperature controller keeps the second temperature from about 30° C. to 70° C.

6. The device as claimed in claim 1, wherein the gas mixture is adapted for etching an oxide film thereby keeping etching uniformity below 2%.

7. The device as claimed in claim 1, wherein the second source of anhydrous reactive gas comprises a reactive gas capable of providing a steady flow of anhydrous halogen-containing gas and hydrazine, ammonia, carbon dioxide and oxides of nitrogen.

8. The device as claimed in claim 7, wherein the anhydrous halogen-containing gas further comprises anhydrous hydrogen fluoride.

9. The device as claimed in claim 1, wherein the enabling chemical compound is water or an organic compound selected from the group consisting of alcohols, aldehydes, ketone, and carboxylic acids.

10. An apparatus for etching or cleaning a substrate, comprising:
a processing chamber for receiving and treating the substrate;
a gas supply device for providing a gas mixture in the processing chamber, comprising:
a first source of an inert carrier gas, communicated with a first pipeline;
a second source of anhydrous reactive gas, communicated with a second pipeline;
a third source of enabling chemical gas of an enabling chemical compound, communicated with a third pipeline;
a main pipeline, communicated with the first, second, and third pipelines; and
a temperature controller, located on the second pipeline.

11. The apparatus as claimed in claim 10, wherein the temperature controller comprises a heating tape attached on the second pipeline.

12. The apparatus as claimed in claim 10, wherein the second source of an anhydrous reactive gas keeps a first temperature for stabilizing the molecular structure.

13. The apparatus as claimed in claim 12, wherein the temperature controller keeps a second temperature similar to the first temperature.

14. The apparatus as claimed in claim 13, wherein the temperature controller keeps the second temperature from about 30° C. to 70° C.

15. The apparatus as claimed in claim 10, wherein etching or cleaning a substrate further comprises etching an oxide film from the substrate thereby keeping etching uniformity below 2%.

16. The apparatus as claimed in claim 10, wherein the anhydrous reactive gas source comprises a reactive gas capable of providing a steady flow of anhydrous halogen-containing gas and hydrazine, ammonia, carbon dioxide and oxides of nitrogen.

17. The apparatus as claimed in claim 16, wherein the anhydrous halogen-containing gas further comprises anhydrous hydrogen fluoride.

18. The apparatus as claimed in claim 10, wherein the enabling chemical compound is water or an organic compound selected from the group consisting of alcohols, aldehydes, ketone, and carboxylic acids.

19. The apparatus as claimed in claim 10, wherein the gas supply device is configured to prepare said gas mixture outside said processing chamber and to then feed the gas mixture to the processing chamber.
